(19) United States
(12) Patent Application Publication
(10) Pub. No.: US 2025/0244501 A1
(43) Pub. Date: Jul. 31, 2025

(54) Conditioning Hydrocarbon Reservoir Sector Models Using Numerical Well Testing

(71) Applicant: Saudi Arabian Oil Company, Dhahran (SA)

(72) Inventors: Ibrahim M. Al-Abdulwahab, Dhahran (SA); Omar H. Al-Obathani, Dhahran (SA); Etim H. Idorenyin, Dhahran (SA)

(21) Appl. No.: 18/428,879

(22) Filed: Jan. 31, 2024

(51) Int. Cl. G01V 20/00; G06F 30/28

(52) U.S. Cl. CPC G01V 20/00; G06F 30/28

(57) ABSTRACT

Example methods and systems for conditioning hydrocarbon reservoir sector models using numerical well testing are disclosed. One example method includes obtaining well-test data of a well. A reservoir sector model of a sector of a reservoir is obtained, where the sector includes at least an area of the reservoir associated with the well-test data and the well. The reservoir sector model is conditioned by tuning parameters of the reservoir sector model to match a response of the conditioned reservoir sector model to the well-test data, where conditioning the reservoir sector model includes adjusting multiple properties in the reservoir sector model based on the well-test data and at least one of well logs, production logging surveys, or distributed pressure measurements associated with the reservoir. The conditioned reservoir sector model is provided to determine properties of the reservoir for robust reservoir simulation and efficient development of underlying hydrocarbon resource of the reservoir.

### TECHNICAL FIELD

The present disclosure relates to computer-implemented methods and systems for conditioning hydrocarbon reservoir sector models using numerical well testing.

### BACKGROUND

Results from pressure transient analysis (PTA) in well-test interpretation based on analytical models are generally averaged over an investigated hydrocarbon reservoir volume and may be difficult to assimilate in full-field reservoir simulation, due to the lack of details in reservoir heterogeneity, fluid and rock properties, and/or well geometry. Well-test interpretation based on numerical models, on the other hand, relies on manual adjustments of model parameters in order to match the numerical models to actual well-test data. The manual adjustment is time consuming and may lead to errors, especially during data management, and is highly subjective to human biases.

### SUMMARY

The present disclosure involves methods and systems for conditioning hydrocarbon reservoir sector models using numerical well testing. One example method includes obtaining, using a hardware processor, well-test data of a well. A reservoir sector model of a sector of a reservoir is obtained using the hardware processor, where the sector includes at least an area of the reservoir associated with the well-test data and the well. The reservoir sector model is conditioned using the hardware processor by tuning parameters of the reservoir sector model to match a response of the conditioned reservoir sector model to the well-test data, where conditioning the reservoir sector model includes adjusting multiple properties in the reservoir sector model based on the well-test data and at least one of well logs, production logging surveys, or distributed pressure measurements associated with the reservoir. The conditioned reservoir sector model is provided using the hardware processor to determine properties of the reservoir for robust reservoir simulation and efficient development of underlying hydrocarbon resource of the reservoir.

The previously described implementation is implementable using a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium. These and other embodiments may each optionally include one or more of the following features.

In some implementations, conditioning the reservoir sector model includes discretizing the reservoir sector model based on a Voronoi gridding scheme to generate a reference model.

In some implementations, conditioning the reservoir sector model further includes determining an upscaled model based on the reference model.

In some implementations, tuning the parameters of the reservoir sector model includes tuning parameters of the upscaled model.

In some implementations, the parameters of the upscaled model includes at least one of permeability multipliers of facies bins, permeability multipliers of layers, perforation length, mechanical skin, or wellbore length of the upscaled model.

In some implementations, tuning the parameters of the upscaled model includes tuning the parameters of the upscaled model based on a derivative-free optimization method.

In some implementations, tuning the parameters of the upscaled model includes tuning the parameters of the upscaled model based on a comparison between a transient response of the upscaled model and a transient response of the reference model.

In some implementations, discretizing the reservoir sector model based on the Voronoi gridding scheme includes storing, in an address register, a correspondence between cells from an original grid of the reservoir sector model and cells from a Voronoi grid, and mapping the tuned parameters of the upscaled model to the reservoir sector model includes translating the tuned parameters of the upscaled model to the reservoir sector model based on the correspondence.

In some implementations, the original grid of the reservoir sector model is a corner-point-geometry grid.

In some implementations, the well-test data includes flow rate data and pressure data associated with the well and acquired during a well test.

In some implementations, adjusting the multiple properties in the reservoir sector model includes adjusting the multiple properties in the reservoir sector model based on one or more characteristics of the well-test data on a log-log graph and the at least one of well logs, production logging surveys, or distributed pressure measurements associated with the reservoir.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example workflow of conditioning a hydrocarbon reservoir sector model using numerical well testing, according to some implementations.

FIG. 2 illustrates an example of a three-dimensional (3D) view of a 70-layer, corner-point-gridded model of a reservoir sector with a tested well, according to some implementations.

FIG. 3 illustrates a comparison between the corner-point-gridded sector model in FIG. 2 and the Voronoi-gridded sector model obtained from the corner-point-gridded sector model, according to some implementations.

FIG. 4 illustrates an example response of running a reference sector model, according to some implementations.

FIG. 5 illustrates a comparison of example responses of upscaled models alongside that of a reference sector model (with 70 layers) on a log-log plot, according to some implementations.

FIG. 6 illustrates example historical test data for the tested well, according to some implementations.

FIG. 7 illustrates an example of a comparison between the response of an upscaled model without regression and the actual well-test data, according to some implementations.

FIG. 8 illustrates an example of a comparison between the response of an upscaled model after regression and the actual well-test data, according to some implementations.

FIG. 9 illustrates an example of a comparison between the response of re-running the reference model (populated with the tuned parameters) and the actual well-test data, according to some implementations.

FIG. 10 illustrates an example transfer of the tuned parameters from the Voronoi-gridded sector model back to the original corner-point-gridded sector model, according to some implementations.

FIG. 11 illustrates an example process for conditioning a hydrocarbon reservoir sector model using numerical well testing, according to some implementations.

FIG. 12 is a block diagram of an example computer system that can be used to provide computational functionalities associated with described algorithms, methods, functions, processes, flows, and procedures, according to some implementations.

FIG. 13 illustrates hydrocarbon production operations that include both one or more field operations and one or more computational operations, which exchange information and control exploration for the production of hydrocarbons, according to some implementations.

Like reference numbers and designations in the various drawings indicate like elements.

### DETAILED DESCRIPTION

This disclosure describes systems and methods that automates conditioning of a hydrocarbon reservoir sector model using numerical well testing. A hydrocarbon reservoir sector model is a segment of a geological model of a hydrocarbon reservoir with limits marked by the drainage area accessed by a well-test of a resident well within the segment. In some cases, a drainage area refers to the extent within a geological model over which a tested well exerts influence. The geological model, however, may not capture the actual field performance correctly and, thus, can be improved by conditioning. Conditioning refers to an engineering process of calibrating and re-distributing the properties in the geological model to represent an actual field behavior, for example, the well-test data.

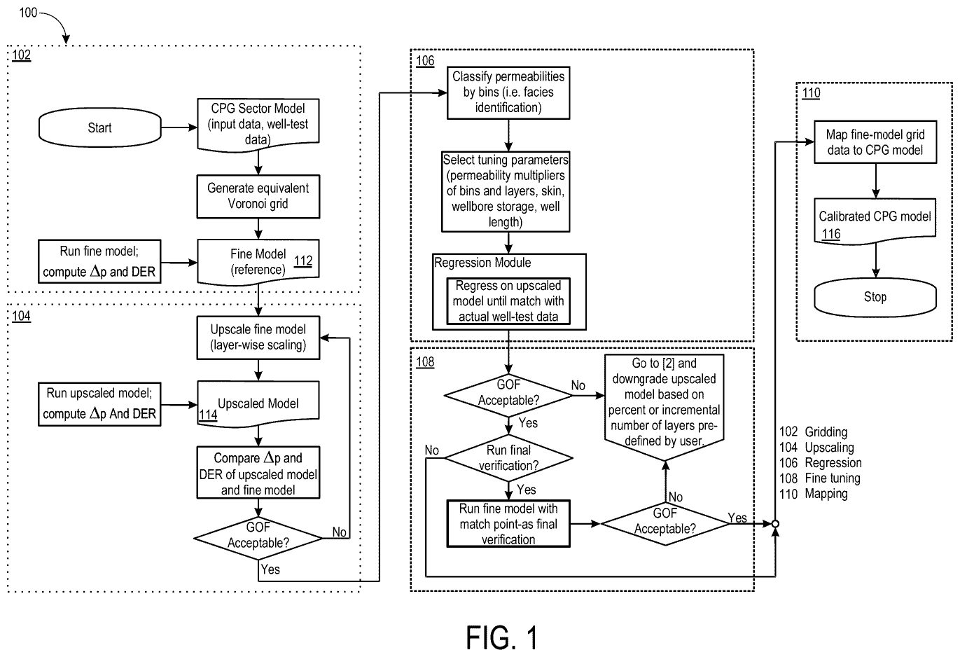

In some cases, the process of conditioning the hydrocarbon reservoir sector model starts from the provision of the hydrocarbon reservoir sector model. Provisioning of the hydrocarbon sector model may include, for example, initializing, preparing, assigning, and activating model components, in view of the reservoir sector and the actual tested well. Example input data to the hydrocarbon reservoir sector model include fluid and rock properties of the hydrocarbon reservoir, well geometry with perforations, well logs, production logging surveys, distributed pressure measurements associated with the hydrocarbon reservoir, or the well-test data (e.g., flow rate and pressure data). Multiphase flow data (including relative permeability and capillary pressure) are provided in the case where more than one fluid phase is produced. The input data can be quality-checked to remove anomalies and noises in the input data that may impact analysis results. In some cases, due to the nature of data measurements in oilfield operations and laboratory experiments, the input data may suffer measurement errors. For example, pressure gauge drifts, laboratory meter malfunctions, and/or wells going on vacuum, can produce anomalous and/or outlier data readings. These errors can lead to difficulties in well-test interpretation. Therefore, the input data can be reviewed to eliminate irregularities before the input data is deployed in pressure transient analysis, for example, in the automated workflow 100 shown in FIG. 1.

In some cases, the well-test data, such as flow rate and pressure data, can be synchronized across the flow periods targeted for pressure transient analysis. If wellhead pressures have been provided, they are converted to their bottom-hole equivalent using appropriate correlations or pipe-flow model(s).

In some cases, data related to the initial reservoir state can be provided for commencing reservoir simulation runs. If, however, the flow periods of interest are further in time, a proximal reservoir state prior to the commencement of the well test may be used.

The disclosed systems and methods provide many advantages over existing systems. As one example, the disclosed methods can ensure that reservoir heterogeneities at the level of the original geological model are captured in the conditioned sector model, alongside the full fluid description, detailed rock properties, and complex well geometry defined in a full-field simulation model. The result of the conditioning of the sector model is an improved subsurface characterization within the reservoir volume described by the conditioned sector model. As another example, the conditioned sector model can be transferred back to the original geological model and used directly to speed up the history-matching loop of a full-field reservoir simulation.

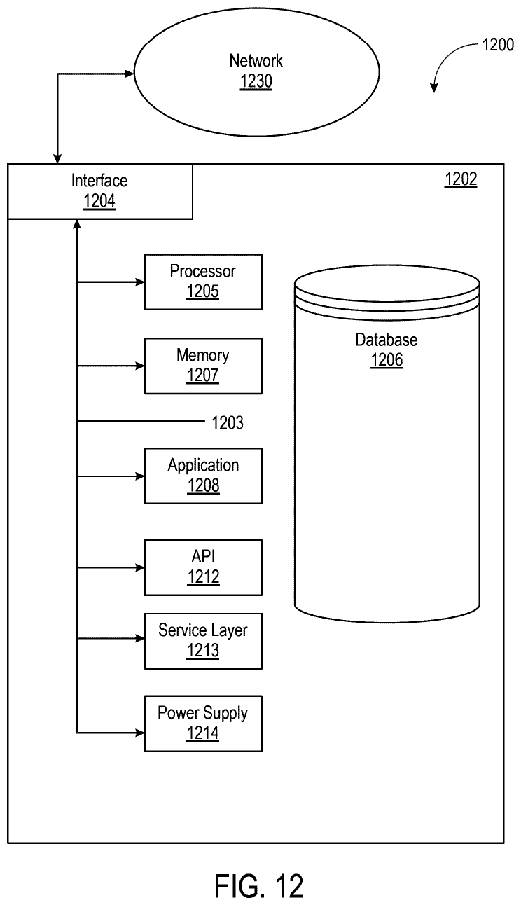

FIG. 1 illustrates an example workflow 100 of conditioning a hydrocarbon reservoir sector model using numerical well testing. For convenience, workflow 100 will be described as being performed by a system of one or more computers, located in one or more locations, and programmed appropriately in accordance with this specification (e.g., the computer system 1200 of FIG. 12).

At 102, a computer system provisions a model of a reservoir sector that includes a tested well for numerical pressure transient analysis by performing lateral discretization (i.e. gridding) of the reservoir sector model. In some implementations, the limits of the reservoir sector model can be defined by the drainage area of the tested well or by the area investigated by the well test. The sector model can then be discretized in space at a scale adequate for simulating the transient performance of the well from early-time through late-time during the well test. Example gridding methods can include corner-point gridding with local grid refinement and/or Voronoi gridding. In some cases, the drainage area can cover grid cells which have experienced a pressure change due to the historical production/injection at the well. A streamline simulation or a visual inspection of a corner-point-grid (CPG) simulation may be used to delineate the drainage area. For example, a trial-and-error method can be used to test different drainage area sizes, beginning with the smallest size, until the transients are no longer detected at the model boundaries. The original vertical discretization of the model is preserved at 102.

In some cases, corner-point gridding produces a structured grid, however, for pressure transient analysis purposes, significant grid refinement may be performed around the tested well and, as a result, lead to excessive computational overhead.

In some implementations, the computer system can use Voronoi gridding to produce an unstructured tessellation. Voronoi gridding is versatile for generating dense grids around the tested well and coarsening grids away from the well. This feature makes Voronoi gridding suitable for pressure transient analysis. As shown in FIG. 1, at 102, Voronoi gridding is used to generate fine model 112 as a reference model of the reservoir sector.

In some implementations, upon completion of gridding, a relatively finely-gridded sector model, e.g., fine model 112, is generated by the computer system and set apart. Fine model 112 can be referred to as a reference model. With the input data entered in the reference model, for example, fluid and rock properties, well geometry and perforations, and initial (or proximal) reservoir state, the computer system can run fine model 112 through the duration of the well test. The model response can be rendered on a log-log graph as both pressure difference and semi-log derivative (DER). This response can be used for reference purposes in workflow 100. In some cases, the original vertical discretization preserved at 102 may contain many grids to the extent that it draws heavily on computing resource.

At 104, the computer system performs layer-wise upscaling to selectively homogenize layers based on user-defined criteria. The result of the layer-wise upscaling is a vertically coarsened sector model, e.g., upscaled model 114. In some cases, vertical upscaling can further simplify the sector model in order to manage computing time efficiently without affecting the model's transient response. In some cases, vertical upscaling can be performed by aggregating contiguous layers not differing in permeability by more than a set threshold, for example, 5%. In some cases, vertical upscaling can be performed automatically, using either a power law or a permeameter rule. In some cases, the aforementioned upscaling methods based on either a power law or a permeameter rule can be combined, giving a user the latitude to select the layers to homogenize based on the power law or the permeameter rule.

In some implementations, the computer system can perform the layer-wise upscaling to the degree that the transient response of upscaled model 114 is not altered. This can be accomplished by running the model through the duration of the well test and comparing its response to that of the reference model (i.e., fine model 112) on a log-log graph plot. Agreement in response between fine model 112 and the upscaled model 114 can be assessed through a goodness-of-fit criterion. This comparison can help to determine upscaled model 114, which will be carried through the rest of workflow 100.

At 106, the computer system performs regression to tune the parameters of upscaled model 114 such that upscaled model 114 simulates actual well-test data. The tuning parameters of interest (e.g. permeability multipliers of facies bins and/or layers, perforation length, mechanical skin, and/or wellbore length) and their physically acceptable range of variability (e.g., both upper and lower bounds) can be specified. Within the regression loop, the computer system adjusts the parameters of upscaled model 114 within the pre-set limits until the model closely replicates actual well-test data. In some cases, regression can be used as a constrained optimization routine for determining the values of the tuning parameters that yield a model response that matches the well-test data. A user can specify the initial value and the bounds for each tuning parameter. The upper and lower bounds can be chosen based on predefined rules, knowledge from analogs, experience of the user, and/or other factors as may be set by the user. The numerical values of the bounds are physically and operationally permissible, for example, bounding effective horizontal well length between 50%-100% of the drilled lateral.

In some implementations, as regression is an optimization procedure that includes multiple runs of upscaled model 114 during parameter tuning, execution time can be a factor in setting up the regression loop. The number of runs used to set up the regression loop can increase drastically if the regression loop is driven by a derivative-based optimizer such as Levenberg-Marquardt type routines. In some cases, the computer system can use derivative-free alternatives, statistical techniques, and machine learning approaches to reduce execution time. In some cases, optimization routines used in pressure-transient analysis that utilize gradient-based algorithms involving multiple evaluations of upscaled model 114 to generate gradient and hessian matrices can lead to long runtimes for numerical well testing. In some cases, derivative-free optimization, for example, differential evolution or simulated annealing, can be used to reduce computational cost associated with optimization routines used in pressure-transient analysis. An example statistical technique is response surface methodology, which can evolve an analytical proxy model to speed up the optimization process significantly. Example machine learning methods can include artificial neural network, convolutional neural network, and/or support vector machine, among others.

At 108, the computer system fine-tunes the regressed upscaled model by first checking the response from the regressed upscaled model for acceptability. In some implementations, acceptability tests the model match from 106 against a goodness-of-fit threshold set by the user. If the response from the regressed upscaled model fails the test, the computer system goes back to 104 to downgrade upscaled model 114, by reverting to a new upscaled model with a higher number of layers than the current upscaled model 114. The new model then goes through 104 and 106 as before. Goodness-of-fit measures the degree of agreement between the regressed upscaled model and actual field behavior. It can be computed as the root-mean-square difference between the model response from 106 and the well-test data. In some cases, an acceptable model is a model for which the goodness of fit does not exceed a threshold set by a user. For example, 5% can be used as a goodness-of-fit threshold. In some cases, goodness-of-fit threshold may vary depending on the complexity of the reservoir sector model and the preference defined by a user.

In some implementations, if the regressed upscaled model from 106 passes the acceptability test, workflow 100 can proceed in one of two directions: either to advance the regressed upscaled model to 110 or export its tuned parameters from 106 to the reference model 112. In the latter case, the computer system runs reference model 112 with tuned parameters and tests its response for acceptability. A positive result implies an improved referenced model which is then advanced to 110. Otherwise, workflow 100 returns to 104 where the regressed upscaled model is downgraded as described earlier.

At 110, the computer system maps the model from 108 onto the original reservoir sector model used at the beginning of 102. In some implementations, the tuned parameters from 106 are translated to the original reservoir sector model, resulting in a conditioned reservoir sector model 116. In some cases, the response of conditioned reservoir sector model 116 can match the well-test data and, thus, provide a basis for accelerating history matching of the underlying full-field reservoir simulation. For example, several sector models conditioned using workflow 100 can be translated back to the original geological framework. Using special geostatistical techniques (e.g. kriging), the conditioned sector models can be used to populate reservoir properties in the inter-sector space across the original geological framework. This updated reservoir property framework can lead to an improved geological model which serves reservoir simulation better than the original geological model, ultimately leading to improved results for guiding reservoir development/management. In some cases, gridding at 102 can convert a corner-point grid to an equivalent Voronoi grid. Along with the conversion, gridding at 102 can also generate an address register which documents the correspondence between cells from the corner-point grid space to those in the Voronoi grid space. At 110, the properties in Voronoi grid can be transferred back to the corner-point grid, based on the correspondence established in the address register.

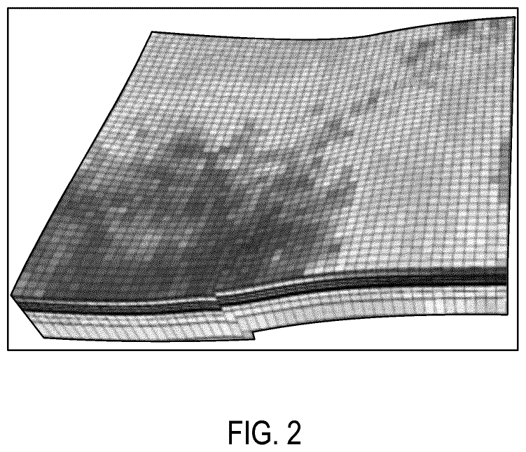

An example of using workflow 100 to generate a conditioned reservoir sector model is shown in FIG. 2 to FIG. 10. FIG. 2 illustrates an example of a three-dimensional (3D) view of a 70-layer, corner-point-gridded model of a reservoir sector with a tested well. At 102, the sector model shown in FIG. 2 is re-discretized using the Voronoi gridding scheme in preparation for pressure transient analysis.

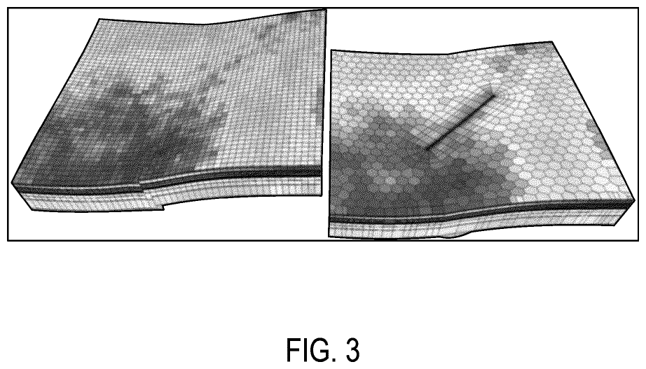

FIG. 3 illustrates a comparison between the corner-point-gridded sector model in FIG. 2 and the Voronoi-gridded sector model obtained from the corner-point-gridded sector model at 102. The comparison shows the correspondence between the two grid patterns. The Voronoi-gridded sector model in FIG. 3 becomes the reference sector model described in 102 of FIG. 1, i.e., the fine model 112 in FIG. 1.

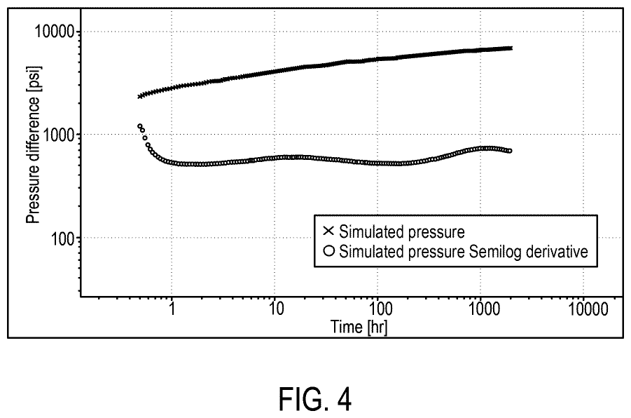

Upon importing all input data, for example, fluid and rock properties, well geometry and perforations, and initial (or proximal) reservoir state, the reference sector model is run using a constant flow rate. FIG. 4 illustrates an example response of running the reference sector model, plotted on a log-log graph in the form of pressure difference and semi-log derivative.

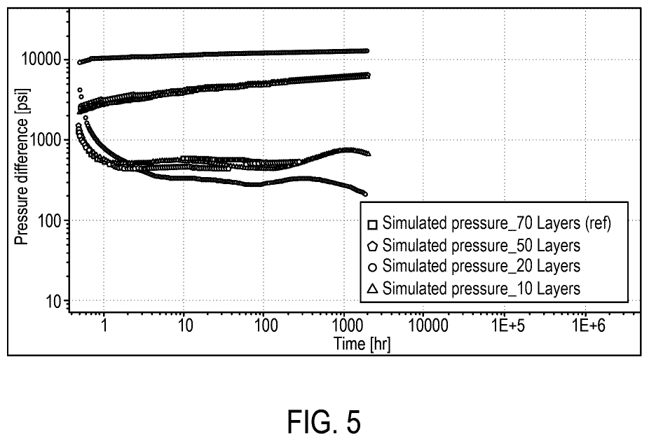

At 104, the computer system homogenizes reservoir layers of the reference sector model based on defined permeability thresholds. Three upscaled models (with 50, 30, and 20 layers) are used. Each one is run using the same constant flow rate as was done for the reference sector model. FIG. 5 illustrates a comparison of the responses of the upscaled models alongside that of the reference sector model (with 70 layers) on a log-log plot.

The 20-layer model response in FIG. 5 shows a marked deviation relative to the reference sector model response. The 30-layer and 50-layer model responses compare acceptably with the reference sector model response. The 30-layer model is selected as the upscaled model 114 for use in this example workflow because of its smaller runtime compared to the 50-layer model.

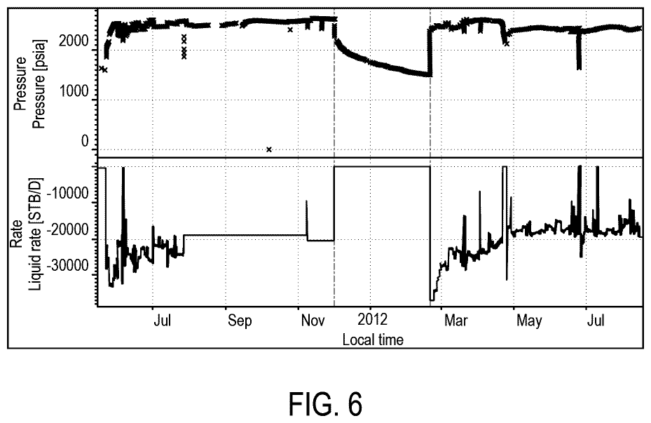

At 106, the computer system uses the actual well-test data to benchmark the response of the upscaled model 114. FIG. 6 illustrates example historical test data for the tested well. The well is a horizontal water injector.

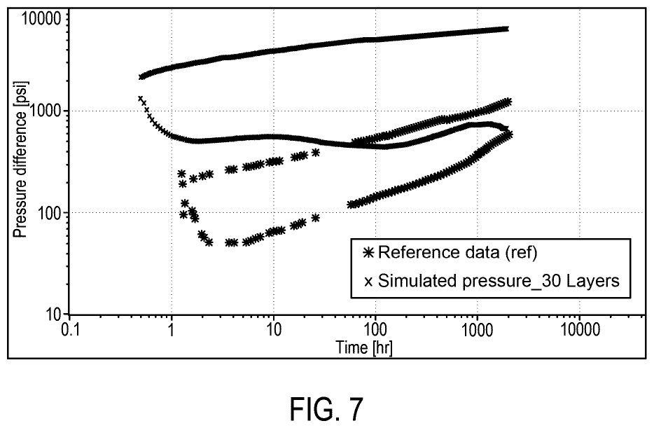

FIG. 7 illustrates an example of a comparison between the response of an upscaled model without regression and the actual well-test data. The mismatch with actual well-test (reference) data shows that the upscaled model 114 without regression underestimates the quality of the reservoir and therefore requires conditioning.

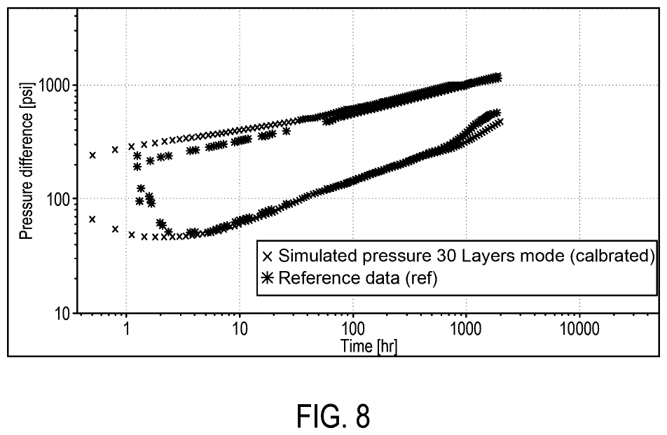

For regression purposes, the permeability multipliers are designated as the tuning parameters in this example case. FIG. 8 illustrates an example of a comparison between the response of the upscaled model 114 after regression and the actual well-test data. As shown in FIG. 8, the response of the upscaled model 114 after regression matches the actual well-test data.

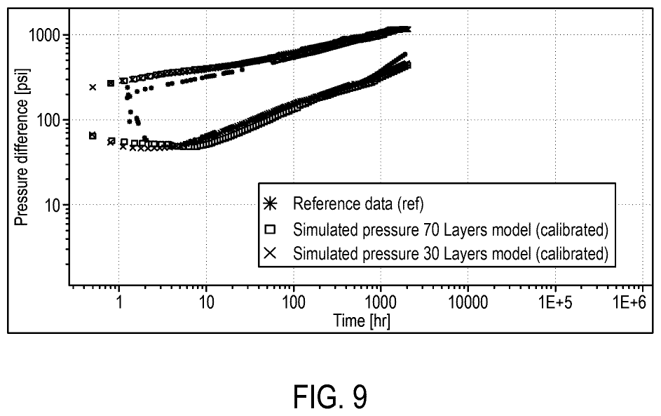

At 108, the computer system tests the regressed upscaled model from 106 for acceptability. A positive test result leads to the transfer of the tuned parameters from the regressed upscaled model to the reference model (with 70 layers); otherwise the workflow returns to 104 and downgrade the upscaled model to the 50-layer model. Since the result at 108 is positive in this example case, the reference model (populated with the tune parameters) is re-run with the actual well-test data. FIG. 9 illustrates an example of a comparison between the response of re-running the reference model (populated with the tuned parameters) at 108 and the actual well-test data. The response matches the well-test data within acceptable limits.

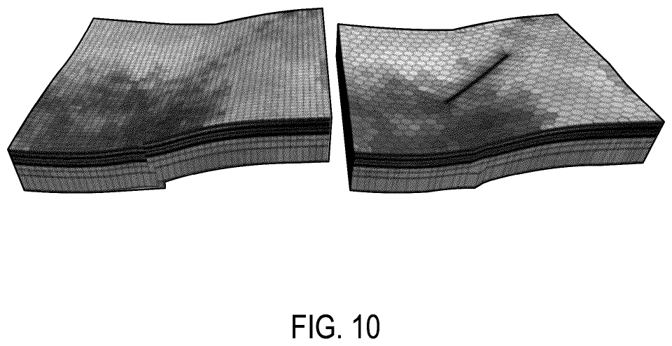

At 110, the computer system translates the tuned parameters from the conditioned reference model to the original corner-point-gridded sector model. FIG. 10 illustrates an example transfer of the tuned parameters from the Voronoi-gridded sector model back to the original corner-point-gridded sector model.

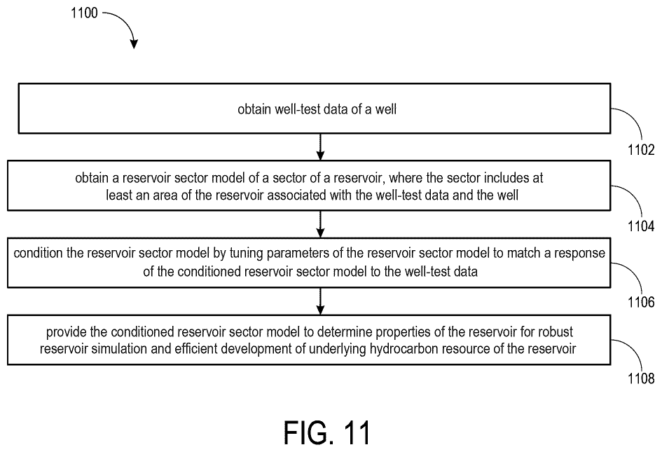

FIG. 11 illustrates an example process 1100 for conditioning a hydrocarbon reservoir sector model using numerical well testing. For convenience, process 1100 will be described as being performed by a computer system having one or more computers located in one or more locations and programmed appropriately in accordance with this specification. An example of the computer system is the computer system 1200 illustrated in FIG. 12.

At 1102, a computer system obtains well test-data of a well.

At 1104, the computer system obtains a reservoir sector model of a sector of a reservoir, where the sector includes at least an area of the reservoir associated with the well-test data and the well.

At 1106, the computer system conditions the reservoir sector model by tuning parameters of the reservoir sector model to match a response of the conditioned reservoir sector model to the well-test data, wherein conditioning the reservoir sector model comprises adjusting a plurality of properties in the reservoir sector model based on the well-test data and at least one of well logs, production logging surveys, or distributed pressure measurements associated with the reservoir.

At 1108, the computer system provides the conditioned reservoir sector model to determine properties of the reservoir for robust reservoir simulation and efficient development of underlying hydrocarbon resource of the reservoir.

FIG. 12 is a block diagram of an example computer system 1200 that can be used to provide computational functionalities associated with described algorithms, methods, functions, processes, flows, and procedures, according to some implementations of the present disclosure. In some implementations, the computer system performing workflow 100 or process 1100 can be the computer system 1200, include the computer system 1200, or the computer system performing workflow 100 or process 1100 can communicate with the computer system 1200.

The illustrated computer 1202 is intended to encompass any computing device such as a server, a desktop computer, an embedded computer, a laptop/notebook computer, a wireless data port, a smart phone, a personal data assistant (PDA), a tablet computing device, or one or more processors within these devices, including physical instances, virtual instances, or both. The computer 1202 can include input devices such as keypads, keyboards, and touch screens that can accept user information. Also, the computer 1202 can include output devices that can convey information associated with the operation of the computer 1202. The information can include digital data, visual data, audio information, or a combination of information. The information can be presented in a graphical user interface (UI) (or GUI). In some implementations, the inputs and outputs include display ports (such as DVI-I+2× display ports), USB 3.0, GbE ports, isolated DI/O, SATA-III (6.0 Gb/s) ports, mPCIe slots, a combination of these, or other ports. In instances of an edge gateway, the computer 1202 can include a Smart Embedded Management Agent (SEMA), such as a built-in ADLINK SEMA 2.2, and a video sync technology, such as Quick Sync Video technology supported by ADLINK MSDK+. In some examples, the computer 1202 can include the MXE-5400 Series processor-based fanless embedded computer by ADLINK, though the computer 1202 can take other forms or include other components.

The computer 1202 can serve in a role as a client, a network component, a server, a database, a persistency, or components of a computer system for performing the subject matter described in the present disclosure. The illustrated computer 1202 is communicably coupled with a network 1230. In some implementations, one or more components of the computer 1202 can be configured to operate within different environments, including cloud-computing-based environments, local environments, global environments, and combinations of environments.

At a high level, the computer 1202 is an electronic computing device operable to receive, transmit, process, store, and manage data and information associated with the described subject matter. According to some implementations, the computer 1202 can also include, or be communicably coupled with, an application server, an email server, a web server, a caching server, a streaming data server, or a combination of servers.

The computer 1202 can receive requests over network 1230 from a client application (for example, executing on another computer 1202). The computer 1202 can respond to the received requests by processing the received requests using software applications. Requests can also be sent to the computer 1202 from internal users (for example, from a command console), external (or third) parties, automated applications, entities, individuals, systems, and computers.

Each of the components of the computer 1202 can communicate using a system bus 1203. In some implementations, any or all of the components of the computer 1202, including hardware or software components, can interface with each other or the interface 1204 (or a combination of both), over the system bus. Interfaces can use an application programming interface (API) 1212, a service layer 1213, or a combination of the API 1212 and service layer 1213. The API 1212 can include specifications for routines, data structures, and object classes. The API 1212 can be either computer-language independent or dependent. The API 1212 can refer to a complete interface, a single function, or a set of APIs 1212.

The service layer 1213 can provide software services to the computer 1202 and other components (whether illustrated or not) that are communicably coupled to the computer 1202. The functionality of the computer 1202 can be accessible for all service consumers using this service layer 1213. Software services, such as those provided by the service layer 1213, can provide reusable, defined functionalities through a defined interface. For example, the interface can be software written in JAVA, C++, or a language providing data in extensible markup language (XML) format. While illustrated as an integrated component of the computer 1202, in alternative implementations, the API 1212 or the service layer 1213 can be stand-alone components in relation to other components of the computer 1202 and other components communicably coupled to the computer 1202. Moreover, any or all parts of the API 1212 or the service layer 1213 can be implemented as child or sub-modules of another software module, enterprise application, or hardware module without departing from the scope of the present disclosure.

The computer 1202 can include an interface 1204. Although illustrated as a single interface 1204 in FIG. 12, two or more interfaces 1204 can be used according to particular needs, desires, or particular implementations of the computer 1202 and the described functionality. The interface 1204 can be used by the computer 1202 for communicating with other systems that are connected to the network 1230 (whether illustrated or not) in a distributed environment. Generally, the interface 1204 can include, or be implemented using, logic encoded in software or hardware (or a combination of software and hardware) operable to communicate with the network 1230. More specifically, the interface 1204 can include software supporting one or more communication protocols associated with communications. As such, the network 1230 or the interface's hardware can be operable to communicate physical signals within and outside of the illustrated computer 1202.

The computer 1202 includes a processor 1205. Although illustrated as a single processor 1205 in FIG. 12, two or more processors 1205 can be used according to particular needs, desires, or particular implementations of the computer 1202 and the described functionality. Generally, the processor 1205 can execute instructions and manipulate data to perform the operations of the computer 1202, including operations using algorithms, methods, functions, processes, flows, and procedures as described in the present disclosure.

The computer 1202 can also include a database 1206 that can hold data for the computer 1202 and other components connected to the network 1230 (whether illustrated or not). For example, database 1206 can be an in-memory, conventional, or a database storing data consistent with the present disclosure. In some implementations, the database 1206 can be a combination of two or more different database types (for example, hybrid in-memory and conventional databases) according to particular needs, desires, or particular implementations of the computer 1202 and the described functionality. Although illustrated as a single database 1206 in FIG. 12, two or more databases (of the same, different, or combination of types) can be used according to particular needs, desires, or particular implementations of the computer 1202 and the described functionality. While database 1206 is illustrated as an internal component of the computer 1202, in alternative implementations, database 1206 can be external to the computer 1202.

The computer 1202 also includes a memory 1207 that can hold data for the computer 1202 or a combination of components connected to the network 1230 (whether illustrated or not). Memory 1207 can store any data consistent with the present disclosure. In some implementations, memory 1207 can be a combination of two or more different types of memory (for example, a combination of semiconductor and magnetic storage) according to particular needs, desires, or particular implementations of the computer 1202 and the described functionality. Although illustrated as a single memory 1207 in FIG. 12, two or more memories 1207 (of the same, different, or combination of types) can be used according to particular needs, desires, or particular implementations of the computer 1202 and the described functionality. While memory 1207 is illustrated as an internal component of the computer 1202, in alternative implementations, memory 1207 can be external to the computer 1202.

An application 1208 can be an algorithmic software engine providing functionality according to particular needs, desires, or particular implementations of the computer 1202 and the described functionality. For example, an application 1208 can serve as one or more components, modules, or applications 1208. Multiple applications 1208 can be implemented on the computer 1202. Each application 1208 can be internal or external to the computer 1202.

The computer 1202 can also include a power supply 1214. The power supply 1214 can include a rechargeable or non-rechargeable battery that can be configured to be either user- or non-user-replaceable. In some implementations, the power supply 1214 can include power-conversion and management circuits, including recharging, standby, and power management functionalities. In some implementations, the power-supply 1214 can include a power plug to allow the computer 1202 to be plugged into a wall socket or a power source to, for example, power the computer 1202 or recharge a rechargeable battery.

There can be any number of computers 1202 associated with, or external to, a computer system including computer 1202, with each computer 1202 communicating over network 1230. Further, the terms “client”, “user”, and other appropriate terminology can be used interchangeably without departing from the scope of the present disclosure. Moreover, the present disclosure contemplates that many users can use one computer 1202 and one user can use multiple computers 1202.

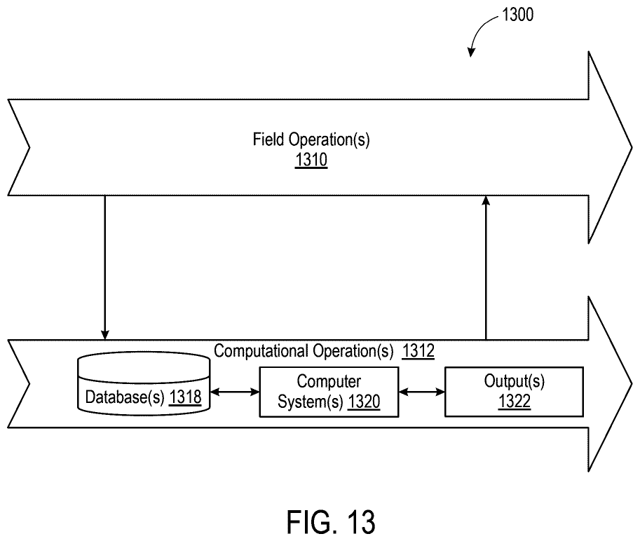

FIG. 13 illustrates hydrocarbon production operations 1300 that include both one or more field operations 1310 and one or more computational operations 1312, which exchange information and control exploration for the production of hydrocarbons. In some implementations, outputs of techniques of the present disclosure can be performed before, during, or in combination with the hydrocarbon production operations 1300, specifically, for example, either as field operations 1310 or computational operations 1312, or both.

Examples of field operations 1310 include forming/drilling a wellbore, hydraulic fracturing, producing through the wellbore, injecting fluids (such as water) through the wellbore, to name a few. In some implementations, methods of the present disclosure can trigger or control the field operations 1310. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 1310 and responsively triggering the field operations 1310 including, for example, generating plans and signals that provide feedback to and control physical components of the field operations 1310. Alternatively or in addition, the field operations 1310 can trigger the methods of the present disclosure. For example, implementing physical components (including, for example, hardware, such as sensors) deployed in the field operations 1310 can generate plans and signals that can be provided as input or feedback (or both) to the methods of the present disclosure.

Examples of computational operations 1312 include one or more computer systems 1320 that include one or more processors and computer-readable media (e.g., non-transitory computer-readable media) operatively coupled to the one or more processors to execute computer operations to perform the methods of the present disclosure. The computational operations 1312 can be implemented using one or more databases 1318, which store data received from the field operations 1310 and/or generated internally within the computational operations 1312 (e.g., by implementing the methods of the present disclosure) or both. For example, the one or more computer systems 1320 process inputs from the field operations 1310 to assess conditions in the physical world, the outputs of which are stored in the databases 1318. For example, seismic sensors of the field operations 1310 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 1312 where they are stored in the databases 1318 and analyzed by the one or more computer systems 1320.

In some implementations, one or more outputs 1322 generated by the one or more computer systems 1320 can be provided as feedback/input to the field operations 1310 (either as direct input or stored in the databases 1318). The field operations 1310 can use the feedback/input to control physical components used to perform the field operations 1310 in the real world.

For example, the computational operations 1312 can process the seismic data to generate three-dimensional (3D) maps of the subsurface formation. The computational operations 1312 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 1312 to process new information about the formation and control the drilling to adjust to the observed conditions in real-time.

The one or more computer systems 1320 can update the 3D maps of the subsurface formation as information from one exploration well is received and the computational operations 1312 can adjust the location of the next exploration well based on the updated 3D maps. Similarly, the data received from production operations can be used by the computational operations 1312 to control components of the production operations. For example, production well and pipeline data can be analyzed to predict slugging in pipelines leading to a refinery and the computational operations 1312 can control machine operated valves upstream of the refinery to reduce the likelihood of plant disruptions that run the risk of taking the plant offline.

In some implementations of the computational operations 1312, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

Implementations of the subject matter and the functional operations described in this specification can be implemented in digital electronic circuitry, in tangibly embodied computer software or firmware; in computer hardware, including the structures disclosed in this specification and their structural equivalents; or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus”, “computer”, and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus and special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, Linux, Unix, Windows, Mac OS, Android, or iOS.

A computer program, which can also be referred to or described as a program, software, a software application, a module, a software module, a script, or code can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document; in a single file dedicated to the program in question; or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes; the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks, optical memory devices, and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), or a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser. Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, or in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations; and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

### EMBODIMENTS

Embodiment 1: A computer-implemented method comprising: obtaining, using a hardware processor, well-test data of a well; obtaining, using the hardware processor, a reservoir sector model of a sector of a reservoir, wherein the sector comprises at least an area of the reservoir associated with the well-test data and the well; conditioning, using the hardware processor, the reservoir sector model by tuning parameters of the reservoir sector model to match a response of the conditioned reservoir sector model to the well-test data, wherein conditioning the reservoir sector model comprises adjusting a plurality of properties in the reservoir sector model based on the well-test data and at least one of well logs, production logging surveys, or distributed pressure measurements associated with the reservoir; and providing, using the hardware processor, the conditioned reservoir sector model to determine properties of the reservoir for robust reservoir simulation and efficient development of underlying hydrocarbon resource of the reservoir.

Embodiment 2: The computer-implemented method of embodiment 1, wherein conditioning the reservoir sector model comprises discretizing the reservoir sector model based on a Voronoi gridding scheme to generate a reference model.

Embodiment 3: The computer-implemented method of embodiment 2, wherein conditioning the reservoir sector model further comprises determining an upscaled model based on the reference model.

Embodiment 4: The computer-implemented method of embodiment 3, wherein tuning the parameters of the reservoir sector model comprises tuning parameters of the upscaled model.

Embodiment 5: The computer-implemented method of embodiment 4, wherein the parameters of the upscaled model comprises at least one of permeability multipliers of facies bins, permeability multipliers of layers, perforation length, mechanical skin, or wellbore length of the upscaled model.

Embodiment 6: The computer-implemented method of embodiment 4 or 5, wherein tuning the parameters of the upscaled model comprises tuning the parameters of the upscaled model based on a derivative-free optimization method.

Embodiment 7: The computer-implemented method of any one of embodiments 4 to 6, wherein tuning the parameters of the upscaled model comprises tuning the parameters of the upscaled model based on a comparison between a transient response of the upscaled model and a transient response of the reference model.

Embodiment 8: The computer-implemented method of any one of embodiments 3 to 7, wherein discretizing the reservoir sector model based on the Voronoi gridding scheme comprises storing, in an address register, a correspondence between cells from an original grid of the reservoir sector model and cells from a Voronoi grid, and wherein mapping the tuned parameters of the upscaled model to the reservoir sector model comprises translating the tuned parameters of the upscaled model to the reservoir sector model based on the correspondence.

Embodiment 9: The computer-implemented method of embodiment 8, wherein the original grid of the reservoir sector model is a corner-point-geometry grid.

Embodiment 10: The computer-implemented method of any one of embodiments 1 to 9, wherein the well-test data comprises flow rate data and pressure data associated with the well.

Embodiment 11: The computer-implemented method of any one of embodiments 1 to 10, wherein adjusting the plurality of properties in the reservoir sector model comprises adjusting the plurality of properties in the reservoir sector model based on one or more characteristics of the well-test data on a log-log graph and the at least one of well logs, production logging surveys, or distributed pressure measurements associated with the reservoir.

Embodiment 12: A non-transitory computer-readable medium storing one or more instructions executable by a computer system to perform operations comprising: obtaining well-test data of a well; obtaining a reservoir sector model of a sector of a reservoir, wherein the sector comprises at least an area of the reservoir associated with the well-test data and the well; conditioning the reservoir sector model by tuning parameters of the reservoir sector model to match a response of the conditioned reservoir sector model to the well-test data, wherein conditioning the reservoir sector model comprises adjusting a plurality of properties in the reservoir sector model based on the well-test data and at least one of well logs, production logging surveys, or distributed pressure measurements associated with the reservoir; and providing the conditioned reservoir sector model to determine properties of the reservoir for robust reservoir simulation and efficient development of underlying hydrocarbon resource of the reservoir.

Embodiment 13: The non-transitory computer-readable medium of embodiment 12, wherein conditioning the reservoir sector model comprises discretizing the reservoir sector model based on a Voronoi gridding scheme to generate a reference model.

Embodiment 14: The non-transitory computer-readable medium of embodiment 13, wherein conditioning the reservoir sector model further comprises determining an upscaled model based on the reference model.

Embodiment 15: The non-transitory computer-readable medium of embodiment 14, wherein tuning the parameters of the reservoir sector model comprises tuning parameters of the upscaled model.

Embodiment 16: The non-transitory computer-readable medium of embodiment 15, wherein tuning the parameters of the upscaled model comprises tuning the parameters of the upscaled model based on a comparison between a transient response of the upscaled model and a transient response of the reference model.

Embodiment 17: A computer-implemented system, comprising one or more computers; and one or more computer memory devices interoperably coupled with the one or more computers and having tangible, non-transitory, machine-readable media storing one or more instructions that, when executed by the one or more computers, perform one or more operations comprising: obtaining well-test data of a well; obtaining a reservoir sector model of a sector of a reservoir, wherein the sector comprises at least an area of the reservoir associated with the well-test data and the well; conditioning the reservoir sector model by tuning parameters of the reservoir sector model to match a response of the conditioned reservoir sector model to the well-test data, wherein conditioning the reservoir sector model comprises adjusting a plurality of properties in the reservoir sector model based on the well-test data and at least one of well logs, production logging surveys, or distributed pressure measurements associated with the reservoir; and providing the conditioned reservoir sector model to determine properties of the reservoir for robust reservoir simulation and efficient development of underlying hydrocarbon resource of the reservoir.

Embodiment 18: The computer-implemented system of embodiment 17, wherein conditioning the reservoir sector model comprises discretizing the reservoir sector model based on a Voronoi gridding scheme to generate a reference model.

Embodiment 19: The computer-implemented system of embodiment 18, wherein conditioning the reservoir sector model further comprises determining an upscaled model based on the reference model.

Embodiment 20: The computer-implemented system of embodiment 19, wherein tuning the parameters of the reservoir sector model comprises tuning parameters of the upscaled model.

We claim:

1. A computer-implemented method comprising:
obtaining, using a hardware processor, well-test data of a well;
obtaining, using the hardware processor, a reservoir sector model of a sector of a reservoir, wherein the sector comprises at least an area of the reservoir associated with the well-test data as well as the well;
conditioning, using the hardware processor, the reservoir sector model by tuning parameters of the reservoir sector model to match a response of the conditioned reservoir sector model to the well-test data, wherein conditioning the reservoir sector model comprises adjusting a plurality of properties in the reservoir sector model based on the well-test data and at least one of well logs, production logging surveys, or distributed pressure measurements associated with the reservoir; and
providing, using the hardware processor, the conditioned reservoir sector model to determine properties of the reservoir for robust reservoir simulation and efficient development of underlying hydrocarbon resource of the reservoir.

2. The computer-implemented method of claim 1, wherein conditioning the reservoir sector model comprises discretizing the reservoir sector model based on a Voronoi gridding scheme to generate a reference model.

3. The computer-implemented method of claim 2, wherein conditioning the reservoir sector model further comprises determining an upscaled model based on the reference model.

4. The computer-implemented method of claim 3, wherein tuning the parameters of the reservoir sector model comprises tuning parameters of the upscaled model.

5. The computer-implemented method of claim 4, wherein the parameters of the upscaled model comprises at least one of permeability multipliers of facies bins, permeability multipliers of layers, perforation length, mechanical skin, or wellbore length of the upscaled model.

6. The computer-implemented method of claim 4, wherein tuning the parameters of the upscaled model comprises tuning the parameters of the upscaled model based on a derivative-free optimization method.

7. The computer-implemented method of claim 4, wherein tuning the parameters of the upscaled model comprises tuning the parameters of the upscaled model based on a comparison between a transient response of the upscaled model and a transient response of the reference model.

8. The computer-implemented method of claim 3, wherein discretizing the reservoir sector model based on the Voronoi gridding scheme comprises storing, in an address register, a correspondence between cells from an original grid of the reservoir sector model and cells from a Voronoi grid, and wherein mapping the tuned parameters of the upscaled model to the reservoir sector model comprises translating the tuned parameters of the upscaled model to the reservoir sector model based on the correspondence.

9. The computer-implemented method of claim 8, wherein the original grid of the reservoir sector model is a corner-point-geometry grid.

10. The computer-implemented method of claim 1, wherein the well-test data comprises flow rate data and pressure data associated with the well and acquired during a well test.

11. The computer-implemented method of claim 1, wherein adjusting the plurality of properties in the reservoir sector model comprises adjusting the plurality of properties in the reservoir sector model based on one or more characteristics of the well-test data on a log-log graph and the at least one of well logs, production logging surveys, or distributed pressure measurements associated with the reservoir.

12. A non-transitory computer-readable medium storing one or more instructions executable by a computer system to perform operations comprising:
obtaining well-test data of a well;
obtaining a reservoir sector model of a sector of a reservoir, wherein the sector comprises at least an area of the reservoir associated with the well-test data as well as the well;
conditioning the reservoir sector model by tuning parameters of the reservoir sector model to match a response of the conditioned reservoir sector model to the well-test data, wherein conditioning the reservoir sector model comprises adjusting a plurality of properties in the reservoir sector model based on the well-test data and at least one of well logs, production logging surveys, or distributed pressure measurements associated with the reservoir; and
providing the conditioned reservoir sector model to determine properties of the reservoir for robust reservoir simulation and efficient development of underlying hydrocarbon resource of the reservoir.

13. The non-transitory computer-readable medium of claim 12, wherein conditioning the reservoir sector model comprises discretizing the reservoir sector model based on a Voronoi gridding scheme to generate a reference model.

14. The non-transitory computer-readable medium of claim 13, wherein conditioning the reservoir sector model further comprises determining an upscaled model based on the reference model.

15. The non-transitory computer-readable medium of claim 14, wherein tuning the parameters of the reservoir sector model comprises tuning parameters of the upscaled model.

16. The non-transitory computer-readable medium of claim 15, wherein tuning the parameters of the upscaled model comprises tuning the parameters of the upscaled model based on a comparison between a transient response of the upscaled model and a transient response of the reference model.

17. A computer-implemented system comprising:
one or more computers; and
one or more computer memory devices interoperably coupled with the one or more computers and having tangible, non-transitory, machine-readable media storing one or more instructions that, when executed by the one or more computers, cause the computer-implemented system to perform one or more operations comprising:
obtaining well-test data of a well;
obtaining a reservoir sector model of a sector of a reservoir, wherein the sector comprises at least an area of the reservoir associated with the well-test data as well as the well;
conditioning the reservoir sector model by tuning parameters of the reservoir sector model to match a response of the conditioned reservoir sector model to the well-test data, wherein conditioning the reservoir sector model comprises adjusting a plurality of properties in the reservoir sector model based on the well-test data and at least one of well logs, production logging surveys, or distributed pressure measurements associated with the reservoir; and
providing the conditioned reservoir sector model to determine properties of the reservoir for robust reservoir simulation and efficient development of underlying hydrocarbon resource of the reservoir.

18. The computer-implemented system of claim 17, wherein conditioning the reservoir sector model comprises discretizing the reservoir sector model based on a Voronoi gridding scheme to generate a reference model.

19. The computer-implemented system of claim 18, wherein conditioning the reservoir sector model further comprises determining an upscaled model based on the reference model.

20. The computer-implemented system of claim 19, wherein tuning the parameters of the reservoir sector model comprises tuning parameters of the upscaled model.
